(19) United States
(12) Patent Application Publication
(10) Pub. No.: US 2006/0156982 A1
(43) Pub. Date: Jul. 20, 2006

(54) Apparatus for fabricating semiconductor device

(75) Inventors: Tae Hwan Kim, Yeoju-gun (KR); Sung Suk Han, Yeoju-gun (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/301,820

(22) Filed: Dec. 12, 2005

(30) Foreign Application Priority Data
Dec. 29, 2004 (KR) 10-2004-0115297

(51) Int. Cl. C23C 16/00; H01L 21/31

(52) U.S. Cl. 118/719; 438/758

(57) ABSTRACT

An apparatus for fabricating semiconductor device is disclosed, which can perform various consecutive processes for wafers. The apparatus includes a chamber zone provided with at least two chambers, a cooling zone, adjacent to the chamber zone, for cooling wafers heated in the chamber zone, a loading zone for loading or unloading the wafers to or from a wafer boat, a transfer device for carrying the wafer boat to the chamber zone, the cooling zone, or the loading zone, and a controller for controlling operations of the chamber zone, the cooling zone and the transfer device.

### CROSS-REFERENCE TO RELATED APPLICATIONS

This application claims the benefit of Korean Application No. P2004-115297 filed on Dec. 29, 2004, which is hereby incorporated by reference as if fully set forth herein.

### BACKGROUND OF THE INVENTION

1. Field of the Invention

The present invention relates to an apparatus for fabricating semiconductor devices, and more particularly, to an apparatus for processing semiconductor wafers that can perform various consecutive processes and that includes multiple chambers that can be operated at the same time.

2. Discussion of the Related Art

To fabricate a semiconductor device, it is necessary to perform various steps. Among the various steps, a CVD (Chemical Vapor Deposition) process may be used to form a polysilicon layer, a nitride layer and/or an oxide layer on a wafer. Also, a diffusion process may be performed by heating or annealing to diffuse impurity ions implanted into a semiconductor substrate.

In this case, apparatuses for performing the CVD process or the diffusion process may be classified into the single wafer apparatus and the arrangement type apparatus. The single wafer apparatus treats one wafer at a time, and the arrangement type apparatus treats a plurality of wafers at the same time. For example, the arrangement type apparatus may include a vertical furnace. A wafer boat with a plurality of wafers may be loaded into the vertical furnace, and the desired process is performed.

In an apparatus for fabricating semiconductor devices according to the related art, as shown in FIG. 1, a vertical furnace 110 is provided at one inner side of an external frame 100. Then, a loading part (not shown) is provided adjacent to the vertical furnace 110, wherein the loading part (not shown) loads a wafer into a wafer boat, or unloads the wafer from the wafer boat. Accordingly, after loading the wafer processed in the prior step into the wafer boat by the loading part (not shown), the wafer boat with the wafer loaded therein is placed in the inside of the vertical furnace 110, and then (for example) a diffusion process is performed.

After completing the diffusion process, the wafer boat is taken out from the vertical furnace 110, and then waits as it cools to an ambient temperature. Then, the wafer boat is transported to the loading part, and the wafer is unloaded.

FIG. 2 illustrates the wafer boat according to the related art. As shown in FIG. 2, the wafer boat carries the plurality of wafers to the inside of the vertical furnace. The wafer boat comprises a top plate 120, a bottom plate 122, and a plurality of rods 124. The plurality of rods 124 are provided between the top plate 120 and the bottom plate 122 to support the top plate 120 and the bottom plate 122, wherein each of the rods have a plurality of slots (not shown). That it, the wafer (w) is loaded in the boat by being inserted into the slots. Generally, about 150 to 170 wafers are loaded into one wafer boat. The wafers positioned in the top and the bottom of the wafer boat may be damaged by injected gas since the top and the bottom of the wafer boat are exposed to gas flowing through the vertical furnace. In this respect, when loading the wafers into the wafer boat, dummy wafers are placed in the top and the bottom slots of the wafer boat.

Even if performing a process for one wafer, it is necessary to provide dummy wafers above and below the wafer. For example, one wafer is processed in a wafer boat adapted for receiving 170 wafers, it may be necessary to provide 169 dummy wafers.

In a wafer foundry, processing is frequently performed on a small quantity of wafers. In this case, in order to obtain film thickness and uniformity within the permitted limits, the process may be performed with the wafer boat completely full of wafers (i.e., provided with dummy wafers in every slot not containing a product wafer).

Accordingly, the number of consumed dummy wafers may be undesirably high, and the maintenance cost per product wafer may increase. Also, since the process is performed on a plurality of wafers, considerable time and energy is consumed for raising or lowering the temperature.

Also, if consecutive processing steps are performed on the plurality of wafers, waiting time between steps is incurred. In addition, a native oxide layer may form on the surface of the wafer during the waiting time, thereby lowering the yield.

### SUMMARY OF THE INVENTION

Accordingly, the present invention is directed to an apparatus for fabricating semiconductor device that substantially obviates one or more problems due to limitations and disadvantages of the related art.

An object of the present invention is to provide an apparatus for fabricating semiconductor device that can perform various consecutive processes for wafers, that can process a relatively small quantity of wafers without substantial waste, and that includes multiple processing chambers that can all operate at the same time.

Additional advantages, objects, and features of the invention will be set forth at least in part in the description which follows and which may in part become apparent to those having ordinary skill in the art upon examination of the following or which may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, an apparatus for fabricating semiconductor devices generally includes a chamber zone having at least two chambers, a cooling zone, adjacent to the chamber zone, for cooling wafers heated in the chamber zone, a loading zone for loading or unloading the wafers to or from a wafer boat, a transfer device for carrying the wafer boat to the chamber zone, the cooling zone, or the loading zone, and a controller for controlling operations of the chamber zone, the cooling zone and the transfer device.

In certain embodiments, the cooling zone includes at least two cooling devices.

Also, in certain embodiments, the maximum number of wafers loaded to each of the wafer boat may be limited to 25 sheets.

In a further embodiment, the same type of process (e.g., heating or annealing, etching, depositing, etc.) may be performed in each of the chambers in the chamber zone. Thus, each of the chambers in the chamber zone may be adapted to perform a substantially identical process. Also, the chambers may be configured to perform consecutive processes in fabricating the semiconductor devices.

In general, the transfer device is positioned between the chamber zone and the cooling and loading zones. Also, the transfer device may include a rail positioned between the chamber zone and the cooling and loading zones, and a boat arm movable along the rail, the boat arm being adapted to transfer the wafer boat between the chamber zone and the cooling and loading zones.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is a perspective view showing a diffusion processing apparatus for fabricating semiconductor device according to the related art;

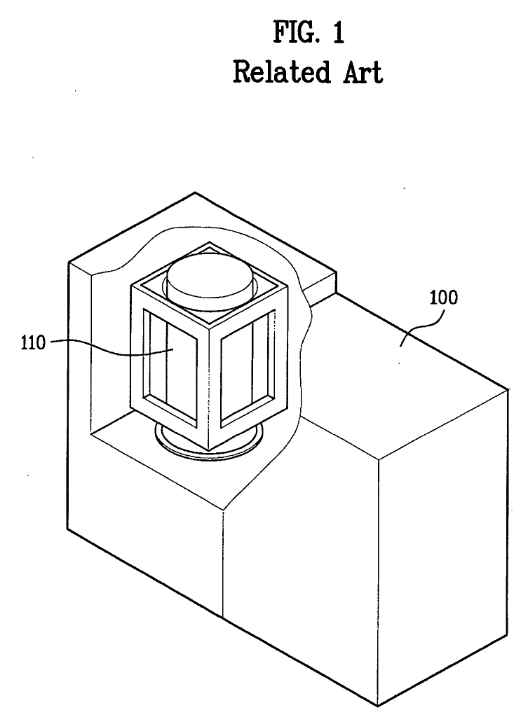

FIG. 2 is a perspective view showing a wafer boat used in a diffusion device of FIG. 1;

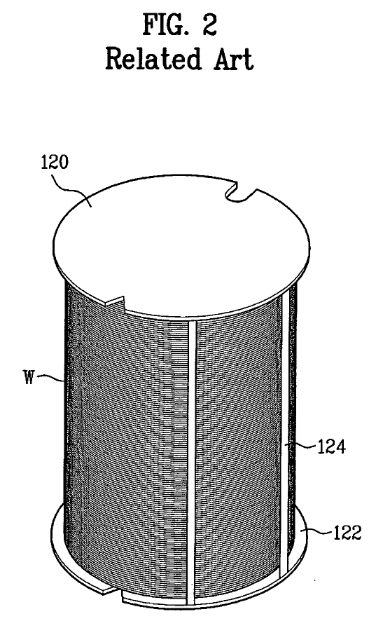

FIG. 3 is a plan view showing an apparatus for fabricating semiconductor devices according to one preferred embodiment of the present invention;

FIG. 4 is a plan view showing an apparatus for fabricating semiconductor devices according to another preferred embodiment of the present invention;

FIG. 5 is a detailed plan view showing an apparatus for fabricating semiconductor devices according to a preferred embodiment of the present invention;

FIG. 6 is a cross-sectional view of a furnace or heating chamber according to one implementation of the present invention;

FIG. 7 is a side view of parts of an apparatus for fabricating semiconductor devices according to a preferred embodiment of the present invention; and

FIG. 8 is a side view of a portion of an apparatus for raising and/or lowering a wafer boat into a vertical chamber according to an embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, an apparatus for fabricating semiconductor devices according to the present invention will be described with reference to the accompanying drawings.

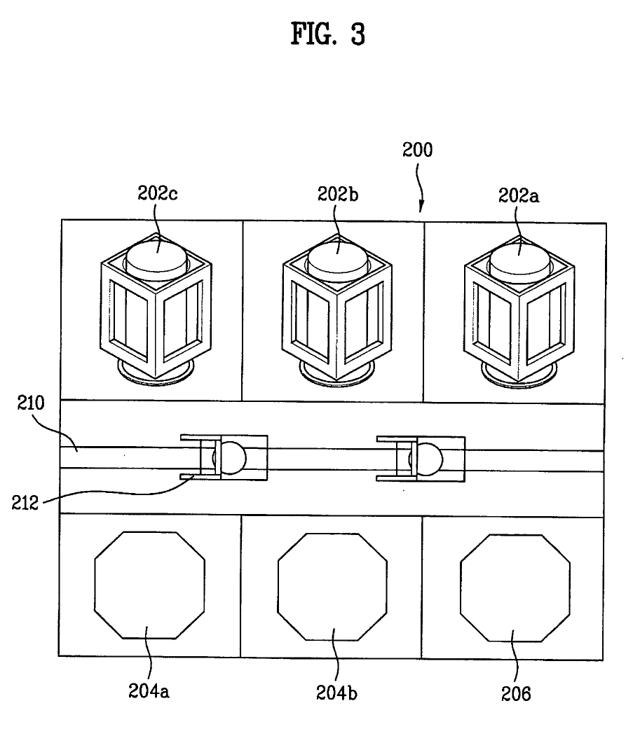

FIG. 3 is a plan view showing an apparatus for fabricating semiconductor devices according to one preferred embodiment of the present invention.

As shown in FIG. 3, an apparatus for fabricating semiconductor devices according to the present invention is provided with various components and an outer frame or housing 200. The outer frame or housing 200 supports the various components. Also, the outer frame or housing 200 has at least six inner divisions, wherein the six inner divisions are arranged in two rows and three columns. Of course, the number and/or arrangement of inner divisions may vary, as may the number of divisions in each zone. For example, the housing 200 may further include a wafer transfer zone or division (e.g., containing transfer mechanism 210/212), one or more wafer storage or stocking divisions or zones, a cassette transfer device or mechanism for transferring wafer cassettes from a wafer storage/stocking division/zone to a transfer zone/division, etc. Generally, however, the housing 200 comprises at least three divisions or zones.

In three of the divisions within housing 200, chambers 202a, 202b and 202c are respectively provided in a chamber zone. The chambers 202a, 202b and 202c are similar in structure to related art wafer processing chambers. However, in the case of the chambers 202a, 202b and 202c according to the present invention, they may have a relatively small size and capacity. For example, each of the chambers 202a, 202b and 202c may have a capacity of 25 wafers. Accordingly, in case of performing process steps on a relatively small number of wafers, it is possible to decrease the number of dummy wafers loaded. Also, since the inner space of the chamber is small, the time and energy for performing a given process step may be decreased in comparison with the related art chambers.

In a preferred embodiment of the present invention, the number of wafers loaded to each of the chambers 202a, 202b and 202c decreases relative to the related art chamber, which may lower productivity. However as shown in FIG. 3 of the drawings, the three chambers 202a, 202b and 202c may be operated together or at the same time, so as to compensate for any decrease of productivity.

That is, the same or similar process may be performed in each of the three chambers 202a, 202b and 202c, or different consecutive processes may be respectively performed in the three chambers 202a, 202b and 202c. For example, if the same process is to be performed on 70 wafers, the wafers may be divided into three lots, and each respective lot loaded into one of the three chambers. Alternatively, if three different thin films (e.g., ‘a’, ‘b’ and ‘c’) are consecutively formed on the surface of the wafer, the first chamber 202a may perform the process of depositing the ‘a’ material or film onto the surface of the wafer, the second chamber 202b may perform the process of depositing the ‘b’ material or film onto the surface of the wafer, and the third chamber 202c may perform the process of depositing the ‘c’ material or film to the surface of the wafer.

Examples of the same process to be performed on wafers in the present apparatus include annealing (e.g., for diffusing dopants implanted into the wafers), wet or dry thermal oxidation (e.g., forming a layer of silicon dioxide by oxidizing exposed silicon surfaces with an oxygen-containing gas such as dioxygen or water vapor under controlled conditions), formation of nitride (e.g., thermal nitridation by reacting exposed silicon or metal such as titanium with a with an nitrogen-containing gas such as dinitrogen or ammonia under controlled conditions), chemical vapor deposition (e.g., formation of a blanket silicon dioxide film from tetraethylorthosilicate [TEOS] vapor in the presence of oxygen gas), etc.

Examples of consecutive processes to be performed on wafers in the present apparatus include, for an overall process of making a shallow trench isolation structure in semiconductor devices, forming a pad (silicon) oxide layer, forming a pad (silicon) nitride layer, and forming a pad (or buffer) TEOS oxide layer (and optionally, annealing the TEOS oxide layer in a fourth chamber); for an overall process of making silicon-oxide-nitride-oxide-silicon (SONOS) non-volatile memory devices, forming a thin (silicon) tunnel oxide layer by thermal oxidation, forming a thin (silicon) nitride charge trapping layer, and forming a thin (silicon) gate oxide layer (e.g., by chemical vapor deposition [CVD] of TEOS or silane in the presence of oxygen); etc.

Thus, it is possible to decrease the time dedicated to or consumed in moving wafers and waiting for equipment to become available, thereby improving the throughput. Also, when the wafers wait for a long time in the ambient atmosphere, a native oxide layer may form on the surface of the wafer. However, in a preferred embodiment of the present invention, by enclosing the processing chambers in a single housing unit, it is possible to prevent the native oxide layer from forming on the surface of the wafer, thereby further eliminating an additional step for cleaning or removing the native oxide layer and (in many cases) further improving the yield.

Meanwhile, one or more cooling zones or stations are provided in the present apparatus, generally opposite to the second chamber 202b and the third chamber 202c. That is, in the embodiment depicted in FIG. 3, two cooling devices or stations 204a and 204b are provided in opposite to the second and third chambers 202b and 202c.

The cooling devices 204a and 204b function as buffers or chambers for temporarily storing the wafers after completing a process in one of the chambers 202a, 202b and/or 202c. Also, the cooling devices 204a and 204b may cool the wafers to a predetermined temperature suitable for the next process (or for completing the current process). In addition, a loading zone or station 206 may provided (in the embodiment depicted in FIG. 3, opposite to the first chamber 202a) for loading the wafers into a wafer boat by a loading device. The loading zone or station 206 may take wafers from a transfer mechanism, such as a standard pod (or standard interface between the wafer processing apparatus and the external environment), and in a preferred embodiment, load the wafers into a wafer boat for (thermal) processing. Of course, a loading zone may comprise two or more loading stations, to improve operational efficiencies.

Also, a transfer device is generally provided between the chambers (e.g., 202a, 202b and 202c), the cooling devices (e.g., 204a and 204b), and the loading zone (e.g., 206). In one embodiment, the transfer device is provided with a rail 210 and a boat arm 212. As shown in FIG. 3, the rail 210 may be provided between the chamber zone (e.g., chambers 202a, 202b and 202c) and the cooling and loading zones (e.g., stations 204a and 204b and loading station 206). The boat arm 212 is generally moved along the rail 210. The boat arm 212 is provided to move the wafer boat, whereby the boat arm 212 moves the wafer boat between the chambers 202a, 202b and 202c and the cooling devices and loading zone 204a, 204b and 206. The boat arm 212 may be arranged in sections with circumferentially rotating joints or connections between sections, to enable motion of the boat arm in a plurality of directions and/or degrees of freedom. In one embodiment, the transfer device may further comprise a mechanism adapted for vertical movement, so that the wafer boat may be raised into or lowered from a vertical chamber (e.g., a vertical furnace). In one embodiment, the vertical transfer mechanism comprises a platform or stage operationally connected to a motor that can raise or lower the wafer boat between the vertical levels of the (horizontal) transfer device (e.g., rail 210 and boat arm 212) and the chamber. Alternatively, the boat arm 212 may be further equipped with a section or portion adapted for changing the vertical position of the wafer boat. Naturally, the present apparatus may be equipped with two or more such transfer devices, to minimize chamber down times (i.e., time periods where a chamber is not processing wafers).

An operation of the apparatus for fabricating semiconductor devices according to the present invention will be described as follows.

First, a method for performing consecutive different processes will be described as follows.

The wafers are transferred to the apparatus for fabricating semiconductor devices by a transfer mechanism (not shown), and then the wafers are loaded to the wafer boat in the loading zone 206. In this state, the wafers for one process are firstly loaded to the wafer boat. If there is an empty space inside the wafer boat, a dummy wafer is provided to the empty space of the wafer boat.

If the wafer boat having the wafers loaded thereon exists in the loading zone 206, the boat arm 212 is moved to the loading zone 206. Then, the boat arm 212 moves the wafer boat having the wafers loaded thereon to the first chamber 202a. At this time, since the first chamber 202a is provided nearest to the loading zone 206, it is possible to minimize the transfer time.

After the wafer boat is provided in the first chamber 202a, the first chamber 202a is driven or operated. Simultaneously, when operating the first chamber 202a, a second lot or group of wafers is loaded onto another wafer boat in the loading zone 206. Thus, it is possible to minimize the operating-stop time period in the present apparatus for fabricating semiconductor devices.

After completing the process in the first chamber 202a, the wafer boat is taken out from the first chamber 202a by the boat arm 212, and then the wafer boat is transferred to cooling zone 204b adjacent to the first chamber 202a. Then, the new wafer boat (after completing the loading of the wafers in the loading zone 206) is provided to the first chamber 202a.

For performing or completing the process performed substantially in the first chamber 202a, the wafers are cooled sufficiently in the second cooling zone 204b. Then, the cooled wafers are loaded to the second chamber 202b, and the next process is performed. If the process in the first chamber 202a is finished before the cooling process, the second group of wafers from the first chamber 202 waits until completing the cooling process for the first group of wafers. In this case, it is possible to minimize the waiting time by controlling the cooling speed of the cooling device 204b.

On completing the processes in the first and second chambers 202a and 202b, the wafer boat is taken out from the second chamber 202b by the boat arm 212. Then, the wafer boat is transferred to the cooling device 204a adjacent to the second chamber 202b. As explained above, after the second wafer boat is taken out from the first chamber 202a, the second wafer boat is transferred to the cooling device 204b adjacent to the first chamber 202a.

During or after that, a third lot or group of wafers are loaded onto another wafer boat in the loading zone 206, and then the third wafer boat having the third lot or group of wafers loaded thereon is provided to the first chamber 202a. Also, the second wafer boat from the cooling device 204b is provided to the second chamber 202b, and the first wafer boat from the cooling device 204a is provided to the third chamber 202c. In this state, the next process is performed.

In the method for fabricating semiconductor devices, consecutive processes may be performed with the plurality of chambers having a relatively small capacity and the wafer boats having a relatively small number of wafers loaded thereon, so that it is possible to reduce waste and manufacturing costs, and improve the yield.

In the case where the same process is performed in the chambers 202a, 202b and 202c, an exemplary operation will be described as follows.

As mentioned above, the wafers are transferred to the apparatus for fabricating semiconductor devices by the transfer mechanism (not shown). Then, the wafers are loaded to the wafer boat(s) in the loading zone 206.

If the wafer boats, each having the wafers loaded thereon, exist in the loading zone 206, the boat arm 212 moves to the loading zone 206. Then, the respective wafer boats are provided to the first, second and third chambers 202a, 202b and 202c by the boat arm 212.

The same process is performed in the first, second and third chambers 202a, 202b and 202c by driving or operating the first, second and third chambers 202a, 202b and 202c under essentially the same set of operating conditions.

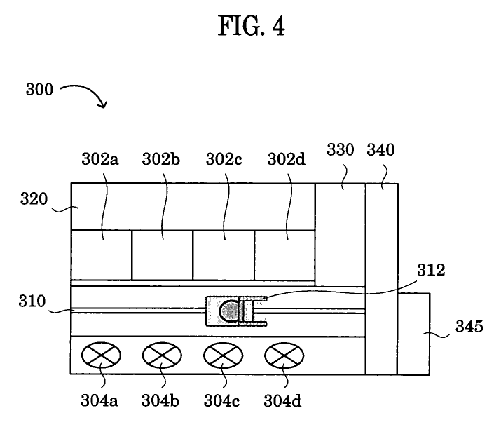

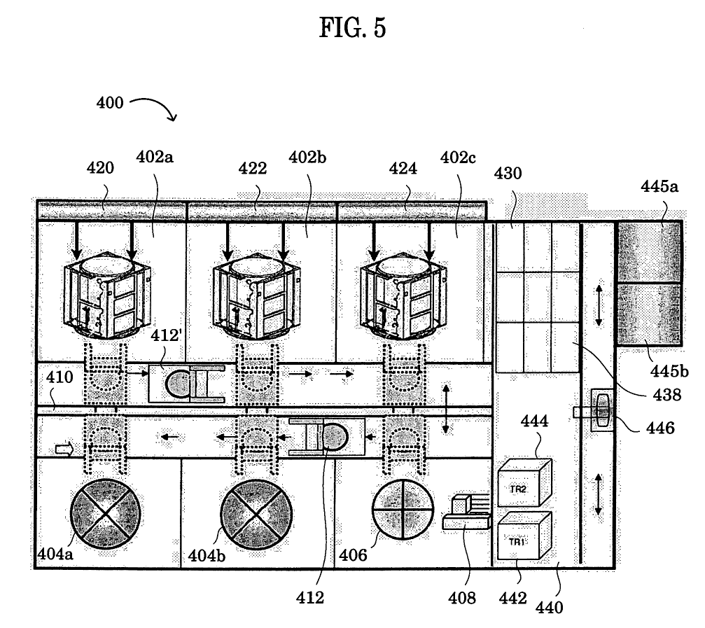

FIG. 4 shows a further embodiment of the present multi-chamber wafer processing apparatus 300, comprising processing zone 302a-302d, inter-chamber waiting (or post-processing) zone 304a-304d, wafer transfer mechanism 310-312, material supply zone 320, wafer storage zone 330, wafer transfer zone 340, and wafer input/output zone 345. As described elsewhere herein, the processing zone may comprise four heating chambers or furnaces 302a-302d; the post-processing zone may comprise four cooling stations 304a-304d; and the wafer transfer mechanism may comprise rail 310 and wafer boat carrier 312 configured to move between heating chambers or furnaces 302a-302d and cooling stations 304a-304d along rail 310. The material supply zone (e.g., gas box) 320 may include containers of various materials (e.g., gas cylinders, tanks or bottles of liquids or slurries, etc.) adapted with pumps, valves, tubes, and/or other mechanisms for supplying the materials to one or more predetermined or desired locations in one or more of the chambers, in accordance with conventionally known techniques for doing so. Wafer storage zone 330, wafer transfer zone 340, and wafer input/output zone 345 will be described on more detail with regard to FIG. 5.

FIG. 5 is detailed plan view of a multi-chamber wafer processing apparatus 400 according to the present invention. Multi-chamber apparatus 400 generally comprises first-third processing chambers 402a-402c, inter-chamber post-processing chambers or zones 404a-404b, and wafer transfer zone (e.g., charge stage) 406 including a wafer cassette-to-wafer boat transfer mechanism 408. A wafer boat transfer mechanism comprising rail 410 and wafer boat carrying apparatuses 412 and (optionally) 412′ move wafer boats between processing and post-processing chambers along rail 410 as described above.

The wafer boat transfer mechanism may comprise a single wafer boat carrying apparatus 412 configured to move along rail 410, turn or rotate by 90° or 180° (as the case may be) and extend the boat (e.g., by extending an arm, platform or fork supporting the boat) into a chamber 402a-406. Alternatively, the wafer boat transfer mechanism may comprise a plurality of wafer boat carrying apparatuses (e.g., 412 and 412′) configured to move wafer boats along upper and lower tracks of rail 410, turn or rotate and extend the boat as described above. In the latter case, each wafer boat carrying apparatus may have its own rail (not shown).

Each processing chamber 402a-402c is provided with its own material supply zone (420, 422 and 424, respectively) in the exemplary embodiment of FIG. 5. Wafer storage zone 430 may be split or divided into a plurality of wafer or wafer cassette storage areas 430-438 (9 such areas are shown in FIG. 5). Wafer transfer zone 440 may comprise first and second wafer transfer apparatuses 442 and 444, each configured to transfer wafers from a wafer cassette to wafer boat loading (charge and discharge) mechanism 408, and vice versa. Wafer cassettes may be retrieved from storage zones (or cassette stocker) 430-438 by wafer cassette transporter 446, which is generally conventional, but which may, in one embodiment, be configured similarly to wafer boat carrying apparatus 412 and rail 410, except that it may include a conventional wafer cassette arm adapted to place the cassette some predetermined horizontal distance in front of the transporter 446. The wafer input/output (“I/O”) zone may comprise first and second wafer cassette pods (or I/O ports) 445a and 445b, configured as is known in the art.

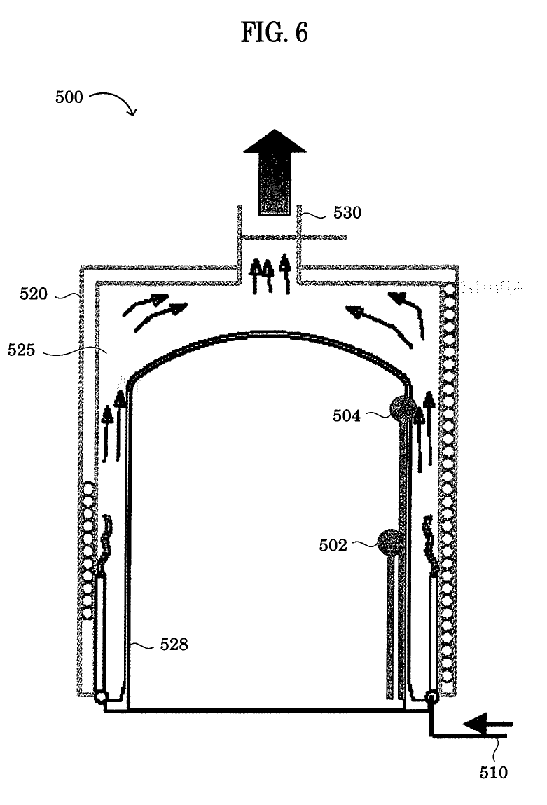

FIG. 6 shows a single furnace (or heating or cooling chamber) 500 suitable for use in the present multi-chamber apparatus. Chamber 500 is configured for rapid heating and/or cooling, which can be controlled using a two-zone system (e.g., comprising first zone temperature detector 502 and second zone temperature detector 504). Of course, the number of different zones (and the number of wafers or wafer lots that can be processed in a given chamber) may vary in accordance with design choices. In general, the larger the number of wafers, the greater the number of zones (e.g., a chamber for 5 wafer lots may comprise 6 zones; a chamber for 1 wafer lot [e.g., 20-25 wafers] may comprise 2 zones; etc.).

Gas inlet 510 allows gas of a predetermined temperature (e.g., heated or cooled in accordance with techniques known in the art) into an inner sleeve 525 of an insulated chamber housing 520. Exhaust 530 may to adapted to remove gas from inner sleeve 525 quickly (e.g., by use of an applied vacuum) to enable rapid replacement of the heated and/or cooled gas inside inner sleeve 525 by temperature-ramped gas provided through inlet 510, in accordance with techniques known in the art. For example, such temperature ramping may occur at a rate of from 10 to 200° C. per minute, 50 to 150° C. per minute, or any range of values therein, and may change in either direction (e.g., heating or cooling). In one embodiment, the temperature ramp in either direction is about 100° C. per minute. Such rapid heating and/or cooling enables relatively short processing times for consecutive processing steps that conventionally take significantly longer (e.g., using single-chamber furnaces or heating equipment). Inner sleeve wall 528 may comprise a highly thermally conductive material (e.g., a metal such as aluminum, copper, steel or titanium) to further enable rapid heating and/or cooling.

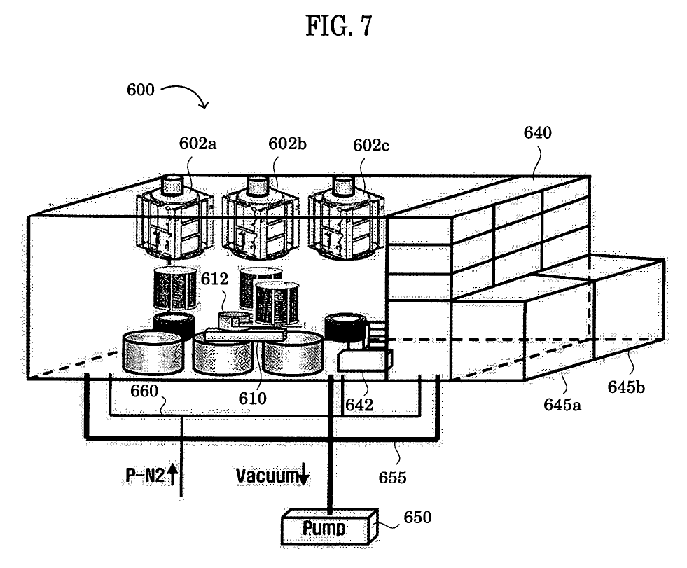

FIG. 7 shows a semi-cutaway view of a further embodiment 600 of the present multi-chamber apparatus. In the apparatus 600, each of the chambers 602a-c is located in an upper portion of the apparatus 600, whereas the wafer boat transporting mechanism (e.g., comprising transporting arm/apparatus 612 and movable rail 610) is located in a lower portion of the apparatus 600. Such a configuration enables accurate placement of the wafer boats under the chambers 602a-c, for facile vertical entry into and exit from the chambers 602a-c.

FIG. 7 also shows a configuration for independent control of the atmosphere and/or ambient within different zones of the apparatus 600. For example, each of the chamber zone (i.e., including chambers 602a-c and wafer boat transporting mechanism) and wafer storage/transfer zone 640 may be provided with one or more gas inlets 660 (which may provide an inert gas such as dinitrogen, He, Ne, Ar, etc.) and one or more gas outlets 655 (operably connected to a vacuum pump 650) for removing and/or exhausting gases from the various zones of the apparatus 600. Such a configuration reduces or eliminates formation of native oxide on an exposed surface of a semiconductor wafer between processing steps. Different zones within apparatus 600 may be sealed from each other and may contain one or more conventional interfaces with each other, as is known in the art.

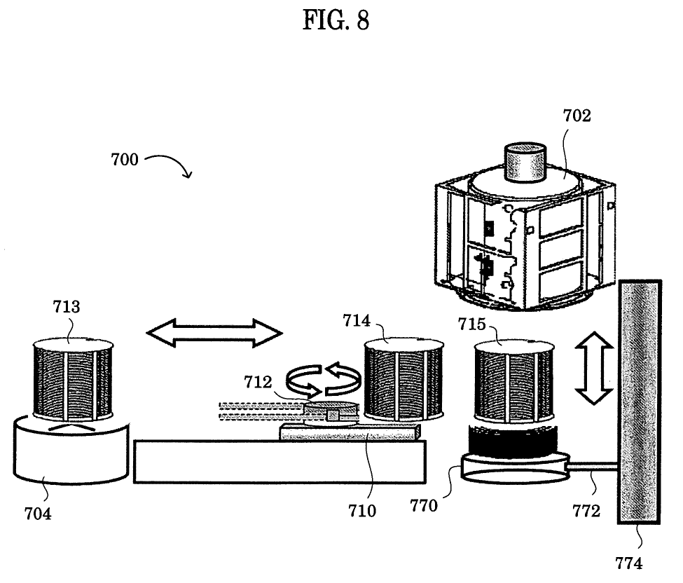

FIG. 8 shows part of an exemplary multi-chamber apparatus 700 containing a mechanism for placing a wafer boat (e.g., 713, 714 or 715) into a vertical chamber 702. Similar to the wafer boat transfer/transporting mechanisms described elsewhere herein, wafer transporting apparatus 712 moves along rail 710 from a first station (e.g., cooling station or stage 704), where it picks up a wafer boat (e.g., 713), to a location proximate to and under a first chamber 702. There, wafer transporting apparatus 712 rotates about 180° and extends the boat (e.g., 714) horizontally until it can be placed on a platform or pedestal 770 fixed via rod or shaft 772 to vertical transfer/transporting mechanism 774. Vertical transfer/transporting mechanism 774 then raises the wafer boat (e.g., 715) until it is in chamber 702, where it is processed generally in accordance with conventional vertical chambers (e.g., a vertical furnace). Thereafter, the wafer boat is lowered from chamber 702 until it is in a position for horizontal transfer back to wafer transporting apparatus 712.

As mentioned above, the apparatus for fabricating semiconductor devices according to the present invention has the following advantages.

First, the apparatus for fabricating semiconductor device according to the present invention comprises a plurality of chambers, where each may have a small size and be adapted for wafer boats, each of which may have a relatively small capacity (i.e., number of slots for loading wafers). Thus, even though the process(es) may be performed on a small number of wafers, it is possible to decrease the number of dummy wafers additionally loaded onto the wafer boat(s). Also, since the chambers may have a small inner space, it is possible to decrease the time and energy for raising or lowering the temperature inside the chamber.

The same or similar process may be performed by the plurality of chambers on different groups or lots of wafers at the same time, so that it is possible to decrease the number of wafers loaded into each of the chambers, thereby improving manufacturing margins.

In the case where consecutive processes are performed in the respective chambers, it is possible to perform the different processes in the respective chambers in sequence, thereby improving the throughput by minimizing the moving and waiting time of the wafers. Also, it is possible to prevent a native oxide layer from being formed on the surface of the wafer during the inter-process waiting time.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. An apparatus for fabricating a semiconductor device comprising:
a chamber zone including at least two chambers;
a cooling zone, adjacent to the chamber zone, for cooling wafers heated in the chamber zone;
a loading zone for loading or unloading the wafers to or from a wafer boat;
a transfer device for carrying the wafer boat to the chamber zone, the cooling zone, or the loading zone;
a controller for controlling operation of the chamber zone, the cooling zone and the transfer device.

2. The apparatus of claim 1, wherein the cooling zone includes at least two cooling devices.

3. The apparatus of claim 1, wherein a maximum number of wafers in the wafer boat is 25.

4. The apparatus of claim 1, wherein each of the chambers in the chamber zone is adapted to perform a substantially identical process.

5. The apparatus of claim 1, wherein the chambers are configured to perform consecutive processes in fabricating the semiconductor device.

6. The apparatus of claim 1, wherein the transfer device is positioned adjacent to the chamber zone, the cooling zone and the loading zone.

7. The apparatus of claim 1, wherein the transfer device includes:
a rail provided between the chamber zone and the cooling and loading zones; and
a boat arm, moveable along the rail, for transferring the wafer boat between the chamber zone and the cooling and loading zones.

8. An apparatus for processing wafers, comprising:
at least two heating chambers;
a first cooling station;
a transfer device for transferring a plurality of the wafers to or from one of the chambers or the first cooling station;
a controller configured to control operations of the chambers, the first cooling station and the transfer device; and
an external housing surrounding the chambers, the first cooling station and the transfer device.

9. The apparatus of claim 8, further comprising a third heating chamber and a second cooling station in the external housing.

10. The apparatus of claim 8, further comprising a loading station for loading or unloading the wafers to or from a wafer boat, wherein the controller is configured to control operations of the loading station.

11. The apparatus of claim 10, wherein the transfer device is positioned adjacent to the heating chambers, the cooling station and the loading station.

12. The apparatus of claim 10, wherein a maximum number of wafers in the wafer boat is 25.

13. The apparatus of claim 8, wherein each of the chambers comprises a furnace.

14. A method of processing wafers, comprising the steps of:
heating a plurality of the wafers in a first heating chamber of a multi-chamber apparatus;
transferring the plurality of wafers from the first heating chamber to a first cooling station in the multi-chamber apparatus;
cooling the plurality of wafers in the first cooling station;
transferring the plurality of wafers from the cooling station to a second heating chamber in the multi-chamber apparatus; and
heating a plurality of the wafers in the second heating chamber.

15. The method of claim 14, further comprising the steps of:
transferring the plurality of wafers from the second heating chamber to a second cooling station in the multi-chamber apparatus;
cooling the plurality of wafers in the second cooling station;
transferring the plurality of wafers from the second cooling station to a third heating chamber in the multi-chamber apparatus; and
heating the plurality of the wafers in the third heating chamber.

16. The method of claim 14, further comprising loading the wafers onto a wafer boat, wherein each of the transferring steps comprises transferring the wafer boat.

17. The method of claim 14, wherein a maximum number of wafers in the wafer boat is 25.

18. The method of claim 14, further comprising controlling conditions of the heating steps, the cooling step and the transferring steps.

19. The method of claim 14, wherein each of the heating chambers comprises a furnace.
